(19) United States
(12) Patent Application Publication
(10) Pub. No.: US 2026/0052982 A1
(43) Pub. Date: Feb. 19, 2026

(54) SEMICONDUCTOR DEVICE AND METHODS OF MAKING THE SAME

(71) Applicant: Taiwan Semiconductor Manufacturing Company Limited, Hsinchu (TW)

(72) Inventors: Tzu Jung Tien, Hsinchu (TW); Jen-Yuan Chang, Hsinchu City (TW)

(21) Appl. No.: 18/809,256

(22) Filed: Aug. 19, 2024

(51) Int. Cl. H01L 23/00; H01L 21/48; H01L 21/56; H01L 23/31; H01L 23/367; H01L 23/538

(52) U.S. Cl. CPC H01L 24/20; H01L 21/4853; H01L 21/4857; H01L 21/565; H01L 23/3128; H01L 23/3675; H01L 23/5383; H01L 23/5386; H01L 24/19; H01L 2224/214

(57) ABSTRACT

An interconnect for a semiconductor device includes a first bonding pad having a first surface, a second bonding pad having a second surface bonded to the first surface of the first bonding pad, and a first guard dummy adjacent the second bonding pad and having a third surface substantially coplanar with the second surface of the second bonding pad.

### BACKGROUND

The galvanic effect, also known as galvanic corrosion, may occur when two dissimilar materials (e.g., dissimilar metals) are in electrical contact with each other in the presence of an electrolyte. This electrical contact may create a galvanic cell where one material acts as the anode and the other material acts as the cathode. This galvanic cell may lead to accelerated corrosion of the anodic material.

The anodic material (e.g., the material with a higher electrochemical potential) may lose electrons (oxidize) and corrode. The cathodic material (e.g., the material with a lower electrochemical potential) may gain electrons (reduce) and be protected from corrosion. The electrolyte may include, for example, water containing dissolved salts or acids. The electrolyte may facilitate the movement of ions between the anodic material and the cathodic material.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a semiconductor device according to one or more embodiments.

FIG. 1B is a transparent top-down view (e.g., plan view) of the semiconductor device according to one or more embodiments.

FIG. 1C is a detailed vertical cross-sectional view of the region R1 in FIG. 1A according to one or more embodiments.

FIG. 1D is a detailed top-down view (e.g., plan view) of the region R2 in FIG. 1B according to one or more embodiments.

FIG. 2A is a vertical cross-sectional view of an intermediate structure including the interposer (e.g., organic interposer) formed on a first carrier substrate (e.g., carrier wafer) according to an embodiment of the present invention.

FIG. 2B is a vertical cross-sectional view of an intermediate structure including the interposer bonding layer after patterning according to one or more embodiments.

FIG. 2C is a vertical cross-sectional view of an intermediate structure including the metal layer according to one or more embodiments.

FIG. 2D is a schematic illustration of a CMP apparatus for performing a CMP process on the intermediate structure in FIG. 2C according to one or more embodiments.

FIG. 2D also includes a top-down view and a vertical cross-sectional view of the interposer bonding layer including the interposer bonding pad and the first guard dummy after the CMP process.

FIG. 2E is a vertical cross-sectional view of an intermediate structure including the interposer bonding layer with a polished surface according to one or more embodiments.

FIG. 2F is a vertical cross-sectional view of an intermediate structure including the first semiconductor die and the second semiconductor dies according to one or more embodiments.

FIG. 2G illustrates a vertical cross-sectional view of an intermediate structure including the molding material layer according to one or more embodiments.

FIG. 2H illustrates a vertical cross-sectional view of an intermediate structure including the plurality of C4 bumps, according to one or more embodiments.

FIG. 3 is a flow chart illustrating a method of forming an interposer module (e.g., semiconductor device) according to one or more embodiments.

FIG. 4A is a top-down view of a plurality of the interconnects having the first alternative design according to one or more embodiments.

FIG. 4B is a vertical cross-sectional view of the interconnect having the first alternative design along the cross-section B-B′ in FIG. 4A.

FIG. 5A is a top-down view of an interconnect having a second alternative design according to one or more embodiments.

FIG. 5B is a top-down view of an interconnect having a third alternative design according to one or more embodiments.

FIG. 5C is a top-down view of an interconnect having a fourth alternative design according to one or more embodiments.

FIG. 5D is a top-down view of an interconnect having a fifth alternative design according to one or more embodiments.

FIG. 6A is a vertical cross-sectional view of the interconnect having the sixth alternative design according to one or more embodiments.

FIG. 6B is a bottom-up view of the bond interface in the interconnect having the sixth alternative design according to one or more embodiments.

FIG. 6C is a top down view of the bond interface in the interconnect having the sixth alternative design according to one or more embodiments.

FIG. 7A is a vertical cross-sectional view of the interconnect having the seventh alternative design according to one or more embodiments.

FIG. 7B is a bottom-up view of the bond interface in the interconnect having the seventh alternative design according to one or more embodiments.

FIG. 7C is a top down view of the bond interface in the interconnect having the seventh alternative design according to one or more embodiments.

FIG. 8 is a vertical cross-sectional view of a package structure including the interposer module according to one or more embodiments.

FIG. 9 is a vertical cross-sectional view of a package module including the interconnect according to one or more embodiments.

FIG. 10 is a vertical cross-sectional view of a package structure including the interconnect according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

The galvanic effect may occur during a process in semiconductor manufacturing. The galvanic effect may be particularly relevant during a chemical mechanical polishing (CMP) process. In instances in which polishing composite films consisting of different metals or metal-dielectric combinations, an electrochemical interaction may occur between the different materials when they are in contact in the CMP slurry which may include an electrolyte solution. This interaction may lead to the accelerated corrosion or oxidation of one material relative to the other.

A surface being polished by the CMP process may include different materials having different electrochemical potentials. The CMP slurry may act as an electrolyte so that a galvanic cell may form between the different materials. The material with the higher electrochemical potential may act as the anode and tend to oxidize (corrode) more readily, while the material with the lower potential may act as the cathode and be protected. The anodic material may undergo an oxidation reaction, leading to material removal or corrosion. The cathodic material may undergo a reduction reaction, but typically it is less affected.

The galvanic effect may lead to uneven material removal rates. For instance, in a copper/tantalum system, copper (being anodic) may corrode faster than tantalum (being cathodic), leading to issues with planarization and film integrity. Accelerated corrosion of the anodic material may create defects such as pitting or increased roughness on a wafer surface, which can negatively impact device performance and yield.

Semiconductor manufacturers may implement several different mitigation strategies to address the galvanic effect during the CMP process. For example, the composition of the CMP slurry (including pH, oxidizers, and inhibitors) may be controlled to mitigate the galvanic effect. Inhibitors may be added to the slurry to prevent excessive corrosion of the anodic material. Additives may be used to passivate the surface or to balance the electrochemical potentials of the different materials involved. The slurry composition may also be optimized to achieve balanced removal rates for all materials. External potentials may be applied to control the electrochemical reactions during CMP. Process parameters such as downforce, platen speed, and slurry flow rate may also be optimized to minimize the effects of galvanic corrosion.

The galvanic effect during the CMP process may be especially relevant in during a bonding process (e.g., a bond that may include a metal-to-metal bond and a dielectric material-to-dielectric material bond). The bond may be used, for example, to bond two structures together in a semiconductor device. The metal-to-metal bond may be formed between bonding pads of the two structures. A bond interface may include a metal-to-metal (e.g., copper-to-copper) interface between surfaces of the bonding pads.

The CMP process may be used to planarize a surface including the bonding pads (e.g., anodic material) in a dielectric material (e.g., cathodic material). The frictional movement and photoelectric effect during the CMP process (e.g., a grinding process) may help to produce a galvanic effect. The galvanic effect may cause the surface (e.g., copper surface) of the bonding pads to be over-removed and produce metal loss (e.g., copper loss). The metal loss may increase a risk of increased interface resistance and decreased reliability.

At least one embodiment of the present disclosure may include an interconnect (e.g., guarded interconnect) and a semiconductor device including the interconnect. The interconnect may be located at the bond interface. At least one embodiment may include an improved design of the bond interface. At least one embodiment may help to reduce the risk of over-removal caused by the galvanic effect during a CMP process used to form one or more of the bonding pads at the bond interface. At least one embodiment may help to reduce a metal loss non-bond defect and improve yield.

The interconnect may include a guard dummy (e.g., guarding dummy pattern design) around at least one bonding pad in the interconnect. The guard dummy may include, for example, a guard ring formed around a bonding pad in the interconnect. During the CMP process, charged ions may first come into contact with the guard dummy. The charged ions may be neutralized by the guard dummy before they come into contact with the bonding pad. Therefore, the galvanic effect-induced metal loss may be inhibited or avoided.

At least one embodiment may include design rules (e.g., guarding dummy pattern design rules) for the guard dummy. In particular, a width of the guard dummy may be greater than 0.01 μm (e.g., about 0.3 μm). A separation distance between the guard dummy and the bonding pad may be greater than 0.1 μm (e.g., about 0.5 μm). A distance between adjacent guard dummies (e.g., guard dummy-to-guard dummy distance) may be greater than 0.1 μm (e.g., about 2 μm). A thickness of the guard dummy may be greater than 0.1 μm (e.g., about 1.5 μm or 2 μm). A thickness of the bonding pad may be substantially the same as the thickness of the guard dummy.

In at least one embodiment, the guard dummy may be connected to the bonding pad (e.g., copper pad). The guard dummy may be electrically isolated (e.g., not connected to other circuits). In at least one embodiment, the interconnect may include a guard dummy for both bonding pads. Thus, at the bond interface, both of the bonding pads may include a guard dummy.

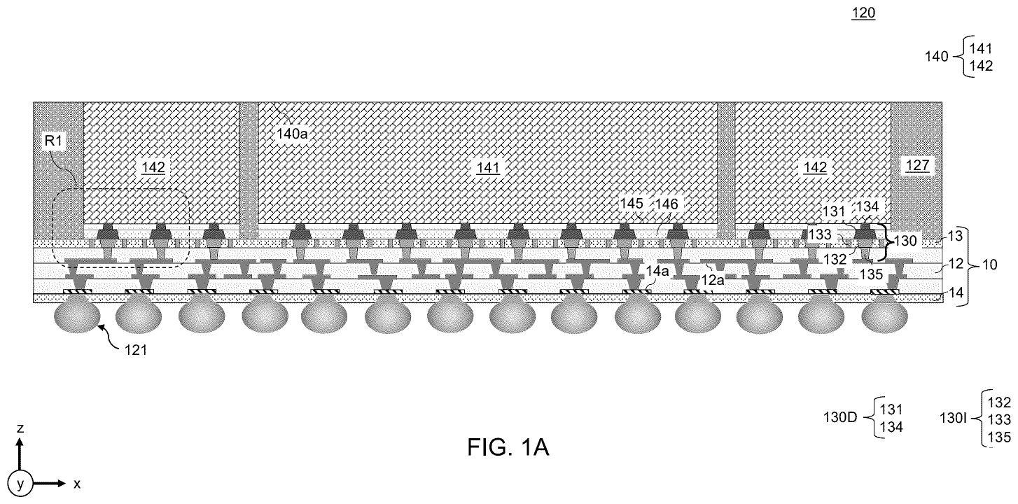

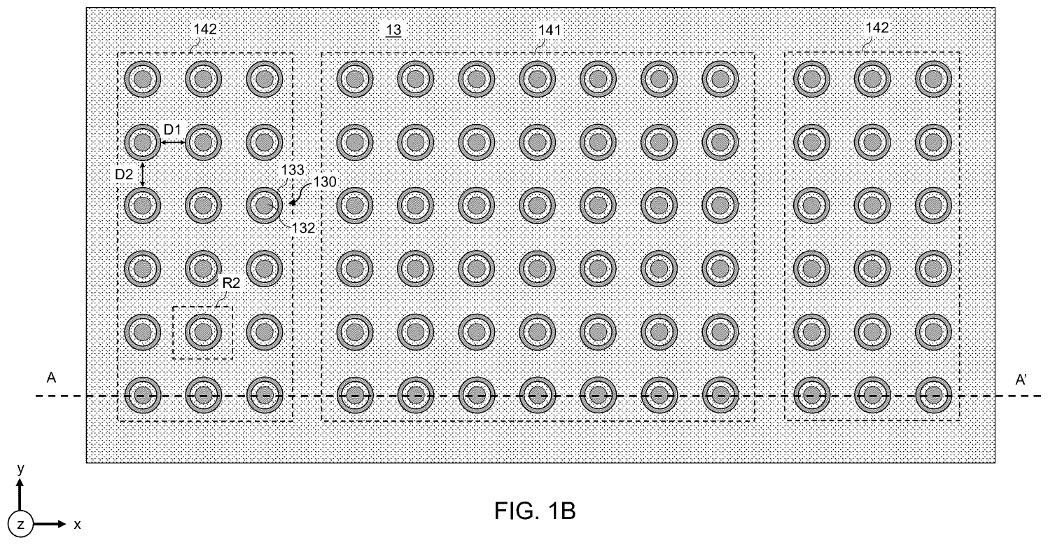

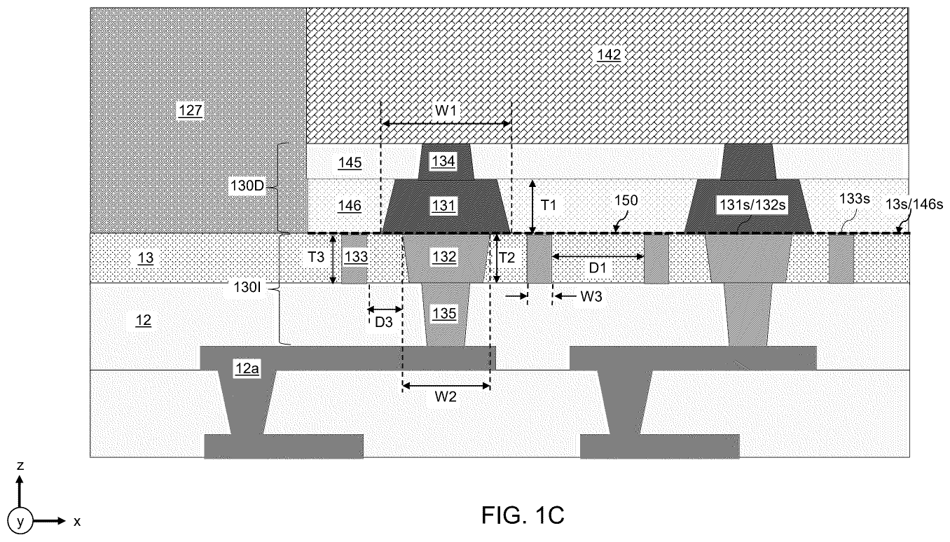

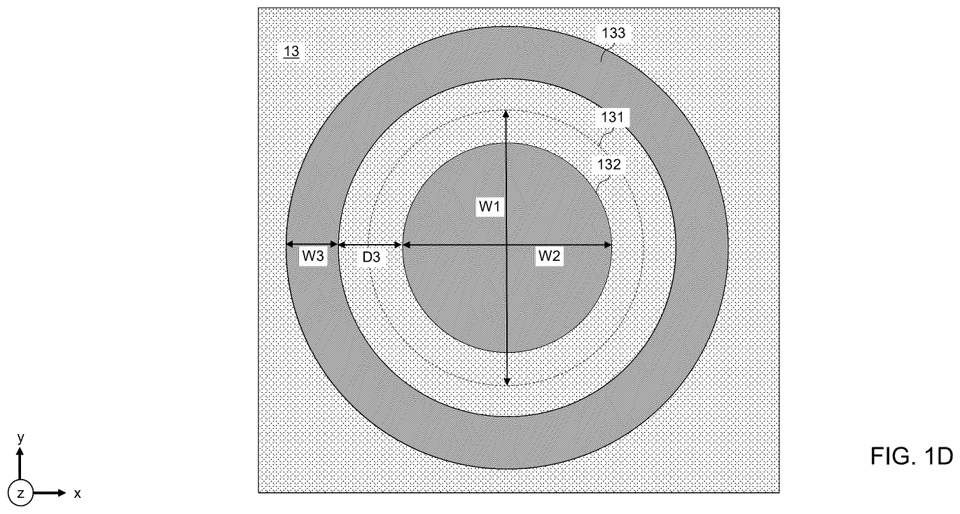

FIG. 1A is a vertical cross-sectional view of a semiconductor device 120 according to one or more embodiments. FIG. 1B is a transparent top-down view (e.g., plan view) of the semiconductor device 120 according to one or more embodiments. FIG. 1A is a vertical cross-sectional view of the semiconductor device 120 along the cross-section A-A′ in FIG. 1B. FIG. 1C is a detailed vertical cross-sectional view of the region R1 in FIG. 1A according to one or more embodiments. FIG. 1D is a detailed top-down view (e.g., plan view) of the region R2 in FIG. 1B according to one or more embodiments.

Generally, the semiconductor device 120 may include an interposer module. The semiconductor device 120 is not limited to an interposer module but may be referred to as interposer module 120 for purposes of describing the semiconductor device in FIGS. 1A-1D.

The interposer module 120 may include one or more semiconductor dies 140 (e.g., first structures) on an interposer 10 (e.g., second structure). The semiconductor dies 140 may be bonded to the interposer 10 by a bond. The interposer module 120 may also include one or more interconnects 130 (e.g., guarded interconnects). The interconnects 130 may electrically couple the semiconductor dies 140 to the interposer 10. The interposer module 120 is not limited to any particular configuration. The interposer module 120 may include, for example, a flip chip-chip scale package (FC-CSP) design, a chip-on-wafer-on-substrate design, an integrated fan-out design, and so on.

The interposer 10 is not necessarily limited to any particular materials or configuration. The interposer 10 may include, for example, organic material (e.g., dielectric polymer), inorganic material (e.g., silicon), glass substrate, etc. In at least one embodiment, the interposer 10 may include a plurality of dielectric material layers 12 and a plurality of redistribution layers 12a stacked alternately. The number of the dielectric material layers 12 and/or the number of redistribution layers 12a in the interposer 10 are not limited by the disclosure.

In at least one embodiment, the dielectric material layers 12 may include, for example, polyimide (PI), epoxy resin, acrylic resin, phenol resin, benzocyclobutene (BCB), polybenzoxazole (PBO), or any other suitable polymer-based dielectric material. In some embodiments, the redistribution layers 12a may include conductive materials. The conductive materials may include metal such as copper, aluminum, nickel, titanium, a combination thereof or other suitable metals. Other dielectric materials and conductive materials are within the contemplated scope of disclosure.

The redistribution layers 12a may include metallic connection structures, i.e., metallic structures that provide electrical connection between nodes in the structure. The redistribution layers 12a may include a metallic seed layer and a metallic fill material on the metallic seed layer. The metallic seed layer may include, for example, a stack of a titanium barrier layer and a copper seed layer. The titanium barrier layer may have thickness in a range from 50 nm to 500 nm, and the copper seed layer may have a thickness in a range from 50 nm to 500 nm. The metallic fill material for the redistribution layers 12a may include copper, nickel, or copper and nickel. Other suitable metallic fill materials are within the contemplated scope of disclosure. The thickness of the metallic fill material that is deposited for each redistribution layer 12a may be in a range from 2 microns to 40 microns, such as from 4 microns to 10 microns, although lesser or greater thicknesses may also be used.

In at least one embodiment, the redistribution layers 12a may include a plurality of traces (lines) and a plurality of vias connecting the plurality traces to each other. The traces may be respectively located on the dielectric material layers 12 and may extend in the x-direction (first horizontal direction) and y-direction (second horizontal direction) on an upper surface of the dielectric material layers 12.

The interposer 10 may also include an interposer bonding layer 13 on the chip-side surface of the interposer 10. The interposer bonding layer 13 may include a dielectric material suitable for forming a bond. In particular, the interposer bonding layer 13 may include silicon oxide, silicon nitride, low-k dielectric materials such as carbon-doped oxides, extremely low-k dielectric materials such as porous carbon doped silicon dioxide, a combination thereof or other suitable material.

The interposer 10 may also include a lower passivation layer 14 on the board-side surface of the interposer 10. The lower passivation layer 14 may be formed of the same materials as the interposer bonding layer 13. The lower passivation layer 14 may include silicon oxide, silicon nitride, low-k dielectric materials such as carbon-doped oxides, extremely low-k dielectric materials such as porous carbon doped silicon dioxide, a combination thereof or other suitable material.

The interposer 10 may also include interposer lower bonding pads 14a in the lowermost dielectric material layer 12. The interposer lower bonding pads 14a may be bonded to and electrically connected to the redistribution layers 12a. The interposer lower bonding pads 14a may alternatively be formed in the lower passivation layer 14. In that embodiment, the lower passivation layer 14 may at least partially cover the interposer lower bonding pads 14a. That is, the interposer lower bonding pads 14a may be at least partially exposed on the board-side surface of the interposer 10. The interposer lower bonding pads 14a may also include, for example, one or more layers and may include metals, metal alloys, and/or other metal-containing compounds (e.g., Cu, Al, Mo, Co, Ru, W, Ti, TiN, Ta, TaN, WN, etc.). Other suitable metal materials are within the contemplated scope of disclosure.

The interposer module 120 may also include a plurality of C4 bumps 121 on the board-side surface of the interposer 10. The C4 bumps 121 may allow the interposer module 120 to be bonded to and electrically coupled, for example, to a package substrate (not shown). The C4 bumps 121 may be formed on the interposer lower bonding pads 14a on the board-side surface of the interposer 10, respectively. The C4 bumps 121 may include underbump metallurgy (UBM) layers (not shown) on the interposer lower bonding pads 14a. The C4 bumps 121 may further include a contact pad (e.g., copper/nickel contact pad) (not shown) on the UBM layers and a solder bump (e.g., SnAg solder bump) on the contact pad.

The semiconductor dies 140 may be attached to the chip-side of the interposer 10. The semiconductor dies 140 may include one or more first semiconductor dies 141 and one or more second semiconductor dies 142. Although the interposer module 120 is illustrated as including a particular number of the semiconductor dies 140 of particular sizes having a particular arrangement, the number of semiconductor dies 140, the sizes of the semiconductor dies 140 and the arrangement of the semiconductor dies 140 is not limited to any particular number, size and arrangement. In particular, the interposer module 120 may include any number, size and arrangement of the semiconductor dies 140.

Generally, a thickness in the z-direction of each of the semiconductor dies 140 may be substantially the same. Thus, the upper surfaces of each of the first semiconductor die 141 and second semiconductor die 142 may be substantially coplanar (e.g., formed in the same x-y plane), and referred to collectively as the semiconductor die upper surface 140a.

Each of the semiconductor dies 140 may include, for example, a singular semiconductor die structure, a system on chip die, or a system on integrated chips die, and may be implemented by chip-on-wafer-on-substrate technology or integrated fan-out on substrate technology. In particular, each of the semiconductor dies 140 may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., high-bandwidth memory (HBM) die, hybrid memory cube (HMC), dynamic random access memory (DRAM) die, a Wide I/O die, a M-RAM die, a R-RAM die, a NAND die, static random access memory (SRAM), etc.), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, an IPD die, a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc. Other dies are within the contemplated scope of this disclosure. In at least one embodiment, the first semiconductor die 141 may include a primary die (e.g., SOC die), and the second semiconductor dies 142 may include an ancillary die (e.g., memory/SOC die, HBM die, etc.).

Each of the semiconductor dies 140 may include a dielectric layer 145 on a side of the semiconductor dies 140 facing the interposer 10. The dielectric layer 145 may be formed of the same material as the dielectric material layers 12 in the interposer 10. In at least one embodiment, the dielectric layer 145 may include, for example, silicon oxide, silicon nitride, low-k dielectric materials such as carbon-doped oxides, extremely low-k dielectric materials such as porous carbon doped silicon dioxide, a combination thereof or other suitable material. Other suitable materials may be used.

Each of the semiconductor dies 140 may also include a die bonding layer 146 on the dielectric layer 145. The die bonding layer 146 may be formed of the same material as the interposer bonding layer 13. The die bonding layer 146 may include a dielectric material suitable for forming a bond. In particular, the die bonding layer 146 may include silicon oxide, silicon nitride, low-k dielectric materials such as carbon-doped oxides, extremely low-k dielectric materials such as porous carbon doped silicon dioxide, a combination thereof or other suitable material.

The interposer module 120 may also include an upper molding layer 127 formed around the semiconductor dies 140. The upper molding layer 127 may have an outer sidewall that is substantially aligned with the outer sidewall of the interposer 10. The upper molding layer 127 may also have an upper surface that is substantially uniform (e.g., flat) and substantially coplanar with the upper surface 140a of the semiconductor dies 140.

The upper molding layer 127 may be formed on outer sidewalls of each of the semiconductor dies 140. The upper molding layer 127 may be bonded to the outer sidewalls of each of the semiconductor dies 140. The upper molding layer 127 may also be formed in a die-to-die gap between the semiconductor dies 140 and bonded to the inner sidewalls of the semiconductor dies 140. The upper molding layer 127 may also be bonded to the chip-side surface of the interposer 10 (e.g., the interposer bonding layer 13).

In at least one embodiment, the upper molding layer 127 may be formed of a curable material that may cure to form a hard, solid structure. The upper molding layer 127 may include, for example, epoxy molding compound (EMC). In at least one embodiment, the upper molding layer 127 may include a polymeric material and in particular, an epoxy-based polymeric material. Other suitable molding materials may be used.

In at least one embodiment, the upper molding layer 127 may have a coefficient of thermal expansion (CTE) that is substantially similar to a CTE of the interposer 10. In at least one embodiment, the upper molding layer 127 may include an added material (e.g., filler material added to a polymeric material) for improving a property of the upper molding layer 127 (e.g., thermal conductivity, CTE, etc.). The added material may include, for example, metal powder, metal oxide powder, etc. Other materials in the upper molding layer 127 are within the contemplated scope of the disclosure.

As further illustrated in FIG. 1A, the semiconductor dies 140 may be mounted on the interposer 10 such that the die bonding layer 146 of the semiconductor dies 140 contacts the interposer bonding layer 13 of the interposer 10. The semiconductor dies 140 may be bonded to the interposer 10 by a bond formed at an interface (bond interface) between the die bonding layer 146 and the interposer bonding layer 13.

The interconnects 130 may be formed across the bond interface between the die bonding layer 146 and the interposer bonding layer 13. The interconnects 130 may include a die bonding pad 131 (first bonding pad) in the die bonding layer 146 (first bonding layer). The interconnects 130 may also include an interposer bonding pad 132 (second bonding pad) in the interposer bonding layer 13 (second bonding layer). The interconnects 130 may also include a first guard dummy 133 adjacent the interposer bonding pad 132 in the interposer bonding layer 13.

As illustrated in FIG. 1A, a surface (first surface) of the die bonding pad 131 may contact a surface (second surface) of the interposer bonding pad 132 at the bond interface. The bond may include a bond between the die bonding pad 131 and the interposer bonding pad 132. The first guard dummy 133 may include a surface (third surface) substantially coplanar with the surface of the interposer bonding pad 132. The first guard dummy 133 may be electrically isolated.

The interconnects 130 may also include a die-side via 134 in the dielectric layer 145 of the semiconductor dies 140. The die-side via 134 may contact the die bonding pad 131 and be electrically coupled to the die bonding pad 131. The interconnects 130 may also include an interposer-side via 135 in the uppermost dielectric material layer 12 of the interposer 10. The interposer-side via 135 may contact the interposer bonding pad 132 and be electrically coupled to the interposer bonding pad 132.

The interconnects 130 may include a die-side interconnect portion 130D including the die bonding pad 131 and the die-side via 134. The interconnects 130 may also include an interposer-side interconnect portion 130I including the interposer bonding pad 132, the first guard dummy 133 and the interposer-side via 135.

The die-side interconnect portion 130D (e.g., die bonding pad 131 and die-side via 134) may include one or more layers and may be formed of metals, metal alloys, and/or other metal-containing compounds (e.g., Cu, Al, Mo, Co, Ru, W, Ti, TiN, Ta, TaN, WN, etc.). In at least one embodiment, the die-side interconnect portion 130D may include copper. Other suitable metal materials are within the contemplated scope of disclosure.

The interposer-side interconnect portion 130I (e.g., interposer bonding pad 132, first guard dummy 133 and interposer-side via 135) may be formed of the same material as the die-side interconnect portion 130D. In at least one embodiment, the interposer bonding pad 132 and the first guard dummy 133 may be formed of substantially the same materials (e.g., copper). The interposer side interconnect portion 130I may include one or more layers and may be formed of metals, metal alloys, and/or other metal-containing compounds (e.g., Cu, Al, Mo, Co, Ru, W, Ti, TIN, Ta, TaN, WN, etc.). In at least one embodiment, the interposer-side interconnect portion 130I may include copper. Other suitable metal materials are within the contemplated scope of disclosure.

Referring again to FIG. 1B, the semiconductor dies 140 (including the die-side interconnect portion 130D) and upper molding layer 127 have been omitted for ease of understanding. A location of the first semiconductor die 141 and the second semiconductor die 142 is indicated in FIG. 1B by dashed lines. As illustrated in FIG. 1B, the surface (second surface) of the interposer bonding pad 132 and the surface (third surface) of the first guard dummy 133 may be exposed across the surface of the interposer bonding layer 13.

As further illustrated in FIG. 1B, the interposer bonding pad 132 may have a substantially circular shape. The first guard dummy 133 may be formed around the interposer bonding pad 132 and have a substantially annular shape (e.g., ring shape). The first guard dummy 133 and the interposer bonding pad 132 may have a substantially concentric arrangement. Other suitable shapes and suitable arrangements of the interposer bonding pad 132 and the first guard dummy 133 are within the contemplated scope of disclosure.

The interconnects 130 may be arranged in the shape of one or more two-dimensional arrays. In particular, the interconnects 130 may be arranged in one or more rows extending in a first direction (the x-direction) and one or more columns extending in a second direction (the y-direction). The interconnects 130 may be substantially uniformly arranged over the area of the first semiconductor die 141 and the second semiconductor dies 142. The first guard dummies 133 may have a substantially uniform spacing. In at least one embodiment, a first guard dummy 133 may be separated from an adjacent first guard dummy 133 in the first direction (x-direction) by a first distance D1 greater than 0.1 μm (e.g., about 2 μm). A first guard dummy 133 may also be separated from an adjacent first guard dummy 133 in the second direction (y-direction) by a second distance D2 greater than 0.1 μm (e.g., about 2 μm). The first distance D1 may or may not be substantially the same as the second distance D2.

Referring again to FIGS. 1C and 1D, the bond may be formed at a bond interface 150 between semiconductor dies 140 (e.g., second semiconductor die 142) and the interposer 10. The bond interface 150 is illustrated as a dashed line in FIG. 1C. The bond interface 150 may include a bond (e.g., oxide-oxide bond) between a surface 13s of the interposer bonding layer 13 and a surface 146s of the die bonding layer 146. The bond interface 150 also includes a bond (e.g., metal-metal bond) between a first surface 131s of the die bonding pad 131 and a second surface 132s of the interposer bonding pad 132. As illustrated in FIG. 1C, the second surface 132s of the interposer bonding pad, the third surface 133s of the first guard dummy 133 and the surface 13s of the interposer bonding layer 13 may all be substantially coplanar.

In at least one embodiment, a width W1 (e.g., diameter) of the die bonding pad 131 may be greater than a width W2 (e.g., diameter) of the interposer bonding pad 132 (e.g., see FIG. 1D). The first guard dummy 133 may have a width W3 that is less than with width W1 of the die bonding pad 131 and less than the width W2 of the interposer bonding pad 132. The width W3 of the first guard dummy 133 may be greater than 0.01 μm (e.g., about 0.3 μm). A first separation distance D3 between the first guard dummy 133 and the interposer bonding pad 132 may also be greater than 0.1 μm (e.g., about 0.5 μm).

The die bonding pad 131 may have a thickness T1 that is substantially the same as a thickness of the die bonding layer 146. A thickness T2 of the interposer bonding pad 132 may be substantially the same as the thickness T1 of the die bonding pad 131. The thickness T2 of the interposer bonding pad 132 may or may not be substantially the same as a thickness T3 of the first guard dummy 133. In at least one embodiment, the thickness T3 of the first guard dummy 133 may be greater than the width W3 of the first guard dummy 133. In at least one embodiment, the first guard dummy 133 may or may not extend entirely through the interposer bonding layer 13. The thickness T2 of the interposer bonding pad 132 may be greater than 0.1 μm (e.g., about 1.5 μm or 2 μm). The thickness T3 of the first guard dummy 133 may be greater than 0.1 μm (e.g., about 1.5 μm or 2 μm). In at least one embodiment, the thickness T2 of the interposer bonding pad 132 and the thickness T3 of the first guard dummy 133 may both be substantially the same as a thickness of the interposer bonding film 13.

In at least one embodiment, the first separation distance D3 between the interposer bonding pad 132 and the first guard dummy 133 may be greater than the width W3 of the first guard dummy 133. In at least one embodiment, the first separation distance D3 between the interposer bonding pad 132 and the first guard dummy 133 may be at least 30% greater than the width W3 of the first guard dummy 133. In at least one embodiment, each of the width W3 of the first guard dummy and the first separation distance D3 is substantially uniform around an entire periphery of the second bonding pad 132.

In at least one embodiment, the width W2 of the interposer bonding pad 132 may be greater than the width W3 of the first guard dummy 133. In at least one embodiment, the width W2 of the interposer bonding pad 132 may be at least at least twice the width W3 of the first guard dummy 133. In at least one embodiment, each of the distance D1 between adjacent first guard dummies 133 in the first direction and the distance D2 between adjacent first guard dummies 133 in the second direction may be greater than the first separation distance D3 between the interposer bonding pad 132 and the first guard dummy 133. In at least one embodiment, each of the distance D1 between adjacent first guard dummies 133 in the first direction and the distance D2 between adjacent first guard dummies 133 in the second direction may be at least twice the first separation distance D3 between the interposer bonding pad 132 and the first guard dummy 133.

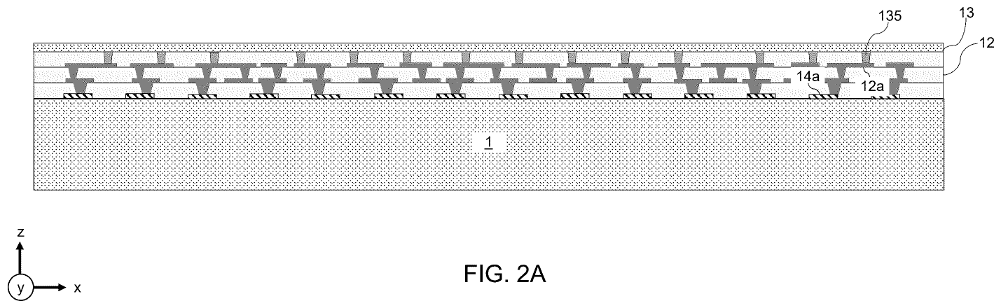

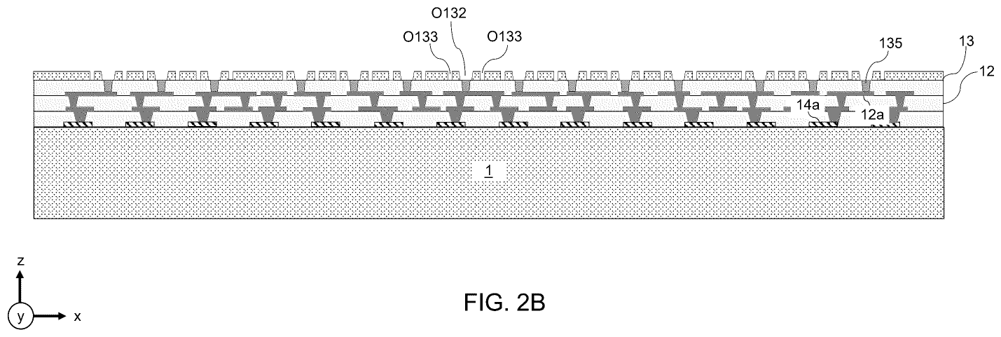

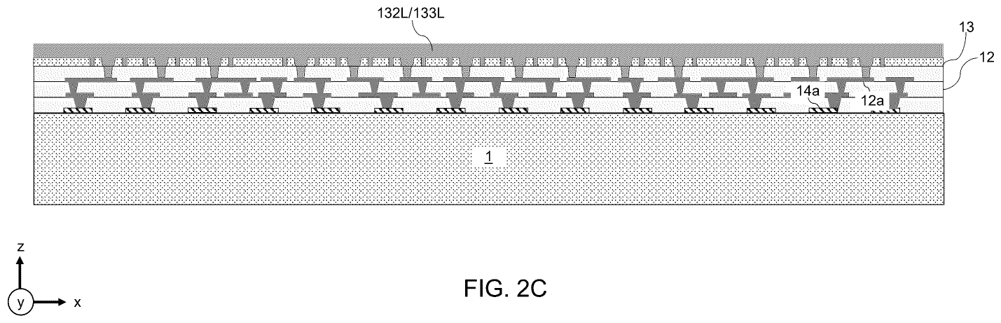

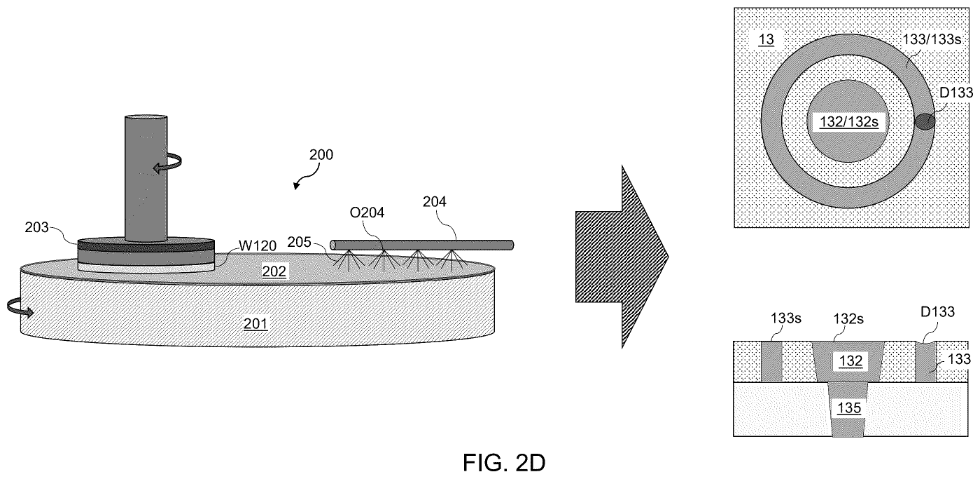

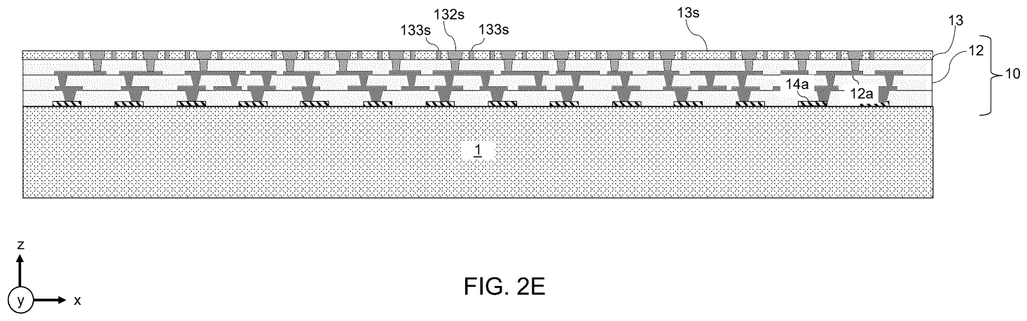

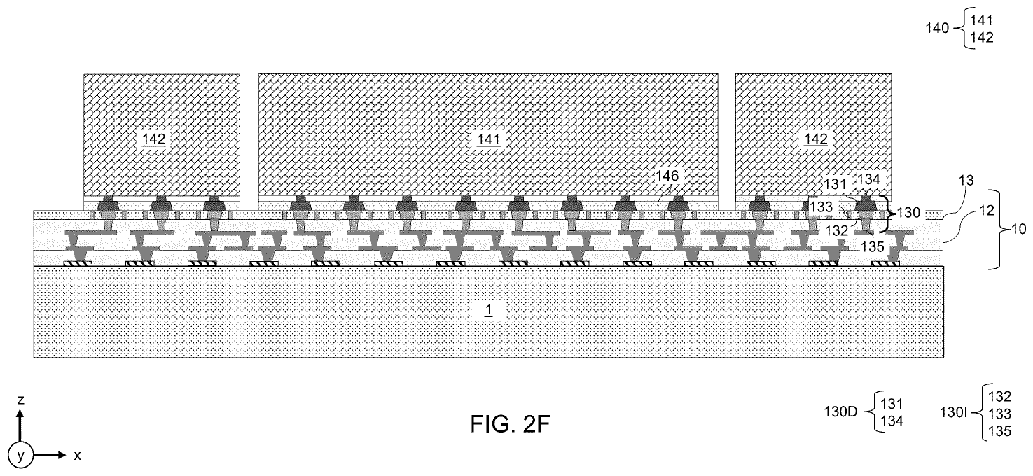

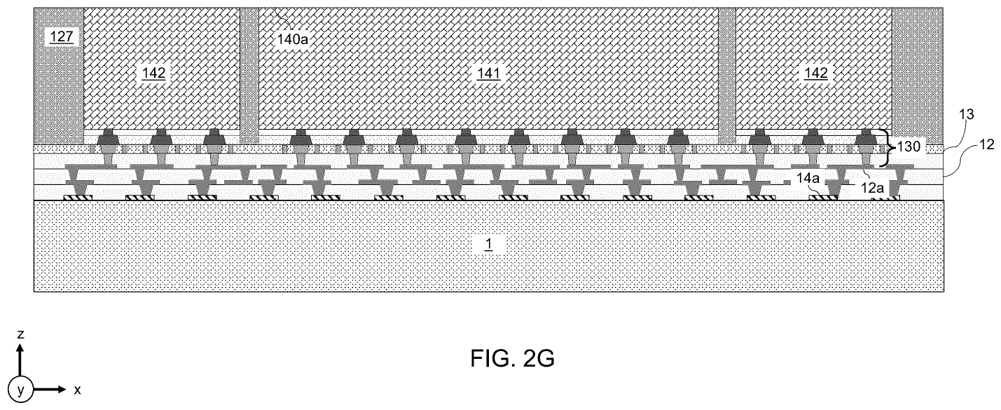

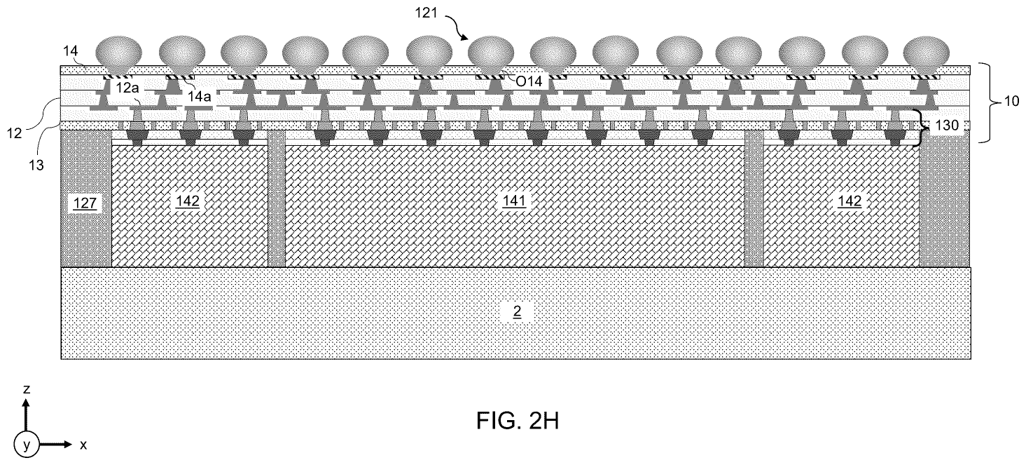

FIGS. 2A-2F illustrate various intermediate structures in a method of forming the interposer module 120 according to one or more embodiments. FIG. 2A is a vertical cross-sectional view of an intermediate structure including the interposer 10 (e.g., organic interposer) formed on a first carrier substrate 1 (e.g., carrier wafer) according to an embodiment of the present invention. The first carrier substrate 1 may include a circular wafer or a rectangular wafer. The lateral dimensions (such as the diameter of a circular wafer or a side of a rectangular wafer) of the first carrier substrate 1 may be in a range from 100 mm to 500 mm, such as from 200 mm to 400 mm, although lesser and greater lateral dimensions may also be used. The first carrier substrate 1 may include a semiconductor substrate, an insulating substrate, or a conductive substrate. The first carrier substrate 1 may be transparent or opaque. The thickness of the first carrier substrate 1 may be sufficient to provide mechanical support to an array of interposers to be formed thereupon. For example, the thickness of the first carrier substrate 1 may be in a range from 60 microns to 1 mm, although lesser and greater thicknesses may also be used.

An adhesive layer (not shown) may be applied to the top surface of the first carrier substrate 1. In one embodiment, the first carrier substrate 1 may include an optically transparent material such as glass or sapphire. In this embodiment, the adhesive layer may include a light-to-heat conversion (LTHC) layer. The LTHC layer is a solvent-based coating applied using a spin coating method. The LTHC layer may form a layer that converts ultraviolet light to heat such that the LTHC layer loses adhesion. Alternatively, the adhesive layer may include a thermally decomposing adhesive material. For example, the adhesive layer may include an acrylic pressure-sensitive adhesive that decomposes at an elevated temperature. The debonding temperature of the thermally decomposing adhesive material may be in a range from 150° C. to 400° C. Other suitable thermally decomposing adhesive materials that decompose at other temperatures are within the contemplated scope of disclosure.

The interposer lower bonding pads 14a may be formed on the adhesive layer. The interposer lower bonding pads 14a may include any metallic material that may be bonded to a solder material. The interposer lower bonding pads 14a may be formed by depositing (e.g., by CVD, PVD or other suitable deposition technique) one or more metal layers including a metal, metal alloys, and/or other metal-containing compounds (e.g., Cu, Al, Mo, Co, Ru, W, Ti, TiN, Ta, TaN, WN, etc.). The metal layer may then be patterned by a photolithographic process so as to form the interposer lower bonding pads 14a. The photolithographic process may include forming a patterned photoresist mask (not shown) on the metallic material, and etching (e.g., wet etching, dry etching, etc.) the exposed upper surface of the metallic material through openings in the photoresist mask. The photoresist mask may be subsequently removed by ashing, dissolving the photoresist mask or by consuming the photoresist mask during the etch process.

In at least one embodiment, the interposer lower bonding pads 14a may include an underbump metallurgy (UBM) layer stack deposited over the adhesive layer. The order of material layers within the UBM layer stack may be selected such that solder material portions may be subsequently bonded to portions of the bottom surface of the UBM layer stack. Layer stacks that may be used for the UBM layer stack include, but are not limited to, stacks of Cr/Cr-Cu/Cu/Au, Cr/Cr-Cu/Cu, TiW/Cr/Cu, Ti/Ni/Au, and Cr/Cu/Au. Other suitable materials are within the contemplated scope of disclosure. The thickness of the UBM layer stack may be in a range from 5 microns to 60 microns, such as from 10 microns to 30 microns, although lesser and greater thicknesses may also be used. A photoresist layer may be applied over the UBM layer stack, and may be lithographically patterned to form an array of discrete patterned photoresist material portions. An etch process may be performed to remove unmasked portions of the UBM layer stack. The etch process may be an isotropic etch process or an anisotropic etch process. Remaining portions of the UBM layer stack may form the interposer lower bonding pads 14a. In at least one embodiment, the interposer lower bonding pads 14a may be arranged as a two-dimensional array, which may be a two-dimensional periodic array such as a rectangular periodic array. In at least one embodiment, the interposer lower bonding pads 14a may be formed as controlled collapse chip connection (C4) bump structures.

The dielectric material layers 12 and redistribution layers 12a (e.g., metal traces and metal vias) may then be alternately formed on the interposer lower bonding pads 14a. It should be noted that although FIG. 2A illustrates three dielectric material layers 12 and two redistribution layers 12a, more or fewer dielectric material layers 12 and redistribution layers 12a are contemplated by the present disclosure.

Each dielectric material layer 12 may each be formed, for example, by depositing (e.g., by CVD, PVD or other suitable deposition technique) a layer of dielectric polymer material such as polyimide (PI), benzocyclobutene (BCB), or polybenzobisoxazole (PBO). Other suitable materials are within the contemplated scope of disclosure. The thickness of the layer of dielectric polymer material may be in a range from 4 microns to 60 microns, although lesser and greater thicknesses may also be used.

The dielectric material layer 12 may then be patterned by a photolithographic process to form via holes in the dielectric material layer 12. The photolithographic process may include forming a patterned photoresist mask (not shown) on the layer of dielectric material, and etching (e.g., wet etching, dry etching, etc.) the exposed upper surface of the dielectric material layer 12 through openings in the photoresist mask. The photoresist mask may be subsequently removed by ashing, dissolving the photoresist mask or by consuming the photoresist mask during the etch process.

A redistribution layer 12a (e.g., metal traces and metal vias) may then be formed on the dielectric material layer 12. The redistribution layer 12a may be formed, for example, by depositing (e.g., by CVD, PVD or other suitable deposition technique) one or more layers of metal material such as copper, aluminum, nickel, titanium, a combination thereof or other suitable metals, on the dielectric material layer 12 and in the vias holes formed by patterning the dielectric material layer 12. The redistribution layer 12a may then be patterned by a photolithographic process. The photolithographic process may include forming a patterned photoresist mask (not shown) on the layer of metal material, and etching (e.g., wet etching, dry etching, etc.) the exposed upper surface of the metal material through openings in the photoresist mask. The photoresist mask may be subsequently removed by ashing, dissolving the photoresist mask or by consuming the photoresist mask during the etch process.

As further illustrated in FIG. 2A, the interposer-side vias 135 may be formed in the uppermost dielectric material layer 12. The interposer-side vias 135 may be formed in a process similar to the process of forming the redistribution layers 12a. The uppermost dielectric material layer 12 may be patterned by a photolithographic process to form via holes in the uppermost dielectric material layer 12. The photolithographic process may include forming a patterned photoresist mask (not shown) on the uppermost dielectric material layer 12, and etching (e.g., wet etching, dry etching, etc.) the exposed upper surface of the uppermost dielectric material layer 12 through openings in the photoresist mask. The photoresist mask may be subsequently removed by ashing, dissolving the photoresist mask or by consuming the photoresist mask during the etch process.

The interposer-side vias 135 may then be formed by depositing (e.g., by CVD, PVD or other suitable deposition technique) one or more layers of metal material such as copper, aluminum, nickel, titanium, a combination thereof or other suitable metals, on the uppermost dielectric material layer 12 and in the vias holes formed by patterning the uppermost dielectric material layer 12. The one or more layers of metal material may then be removed (e.g., by CMP) to expose an upper surface of the interposer-side vias 135 and an upper surface of the uppermost dielectric material layer 12.

The interposer bonding layer 13 may then be formed on the exposed surface of the uppermost dielectric material layer 12 and the interposer-side vias 135. The interposer bonding layer 13 may be formed, for example, by depositing (e.g., by CVD, PVD or other suitable deposition technique) a layer of dielectric material such as silicon oxide, silicon nitride, low-k dielectric materials such as carbon-doped oxides, extremely low-k dielectric materials such as porous carbon doped silicon dioxide, a combination thereof or other suitable material.

FIG. 2B is a vertical cross-sectional view of an intermediate structure including the interposer bonding layer 13 after patterning according to one or more embodiments. As illustrated in FIG. 2B, the interposer bonding layer 13 may be patterned to form openings O132 for the interposer bonding pads 132 and openings O133 for the first guard dummies 133.

The interposer bonding layer 13 may be patterned by a photolithographic process to form the openings O132 and openings O133 in the interposer bonding layer 13. The photolithographic process may include forming a patterned photoresist mask (not shown) on the interposer bonding layer 13, and etching (e.g., wet etching, dry etching, etc.) the exposed upper surface of the interposer bonding layer 13 through openings in the photoresist mask. The photoresist mask may be subsequently removed by ashing, dissolving the photoresist mask or by consuming the photoresist mask during the etch process.

FIG. 2C is a vertical cross-sectional view of an intermediate structure including the metal layer 132L/133L according to one or more embodiments. After the openings O132 and openings O133 are formed in the interposer bonding layer 13, a metal layer 132L/133L may be deposited on the interposer bonding layer 13. The metal layer 132L/133L may substantially fill the openings O132 and openings O133. The metal layer 132L/133L may include a metal material for forming the interposer bonding pads 132 and guard dummies 133. The metal layer 132L/133L may be formed, for example, by depositing (e.g., by CVD, PVD or other suitable deposition technique) one or more layers of metals, metal alloys, and/or other metal-containing compounds (e.g., Cu, Al, Mo, Co, Ru, W, Ti, TiN, Ta, TaN, WN, etc.) on the interposer bonding layer 13 and in the openings O132 and openings O133.

It should be noted that the intermediate structures in FIGS. 2B and 2C are formed only if the interposer bonding pads 132 and the first guard dummies 133 are to be formed of the same material. The interposer bonding pads 132 and the first guard dummies 133 may alternatively be formed of different materials. In such embodiments, for example, the openings O132 may be formed and a metal layer for forming the interposer bonding pads 132 may be deposited and polished. Then, the openings O133 may be formed and a metal layer for forming the first guard dummies 133 may be deposited and polished.

FIG. 2D is a schematic illustration of a CMP apparatus 200 for performing a CMP process on the intermediate structure in FIG. 2C according to one or more embodiments. After the metal layer 132L/133L as illustrated in FIG. 2C is deposited on the interposer bonding layer 13, a CMP process may be performed on a wafer W120 (that carries the intermediate structure of the interposer module 120) using the CMP apparatus 200 in FIG. 2D.

The CMP apparatus 200 may include a rotating platen 201 with a polishing pad 202 on an upper surface of the rotating platen 201. The CMP apparatus 200 may also include a wafer carrier 203 having a lower surface facing the polishing pad 202. The wafer W120 may be attached to the lower surface of the wafer carrier 203 so that the metal layer 132L/133L on the interposer bonding layer 13 faces the polishing pad 202. The CMP apparatus 200 may also include a slurry dispenser 204 having openings O204 for dispensing polishing slurry 205 (e.g., liquid polishing slurry). The polishing slurry 205 may include one or more materials that may include galvanic loss (e.g., SiO₂, AlₓO_{y}, Ca, etc.).

In performing the CMP process, the rotating platen 201 may rotate in a first direction and the wafer carrier 203 may rotate in a second direction opposite the first direction. As the wafer carrier 203 and the rotating platen 201 are rotating and as the polishing slurry 205 is being dispensed onto the polishing pad 202, the wafer carrier 203 may press the wafer W120 down onto the polishing pad 202.

The CMP process may remove the metal layer 132L/133L from the surface 13s of the interposer bonding layer 13. The CMP process may also polish and planarize the surface 13s of the interposer bonding layer 13, the surface 132s of the interposer bonding pad 132 and the surface 133s of the first guard dummy 133. The CMP process may be performed until the metal layer 132L/133L is removed from the surface of the interposer bonding layer 13 so that the metal layer 132L/133L remains only in the openings O132 and openings O133.

FIG. 2D also includes a top-down view and a vertical cross-sectional view of the interposer bonding layer 13 including the interposer bonding pad 132 and the first guard dummy 133 after the CMP process. The first guard dummy 133 may guard the interposer bonding pad 132 from damage caused by the galvanic effect during CMP. In particular, as illustrated in the top-down view and vertical cross-sectional view of the interposer bonding layer 13 in FIG. 2D, an area of galvanic loss D133 may be present on the surface 133s of the first guard dummy 133. However, no area of galvanic loss may be present on the surface 132s of the interposer bonding pad 132.

It should be noted that the first guard dummy 133 may guard the interposer bonding pad 132 from galvanic loss in other processes besides the CMP process. For example, the first guard dummy 133 may guard the interposer bonding pad 132 in a wet clean spin process, lithographic photoresist coating process and a developing spin process which may also induce an electrostatic effect.

FIG. 2E is a vertical cross-sectional view of an intermediate structure including the interposer bonding layer 13 with a polished surface 13s according to one or more embodiments. As illustrated in FIG. 2E, after the CMP process, the polished surface 13s of the interposer bonding layer 13 may be substantially coplanar with the polished surface 132s of the interposer bonding pads 132 and with the polished surface 133s of the first guard dummies 133. The area of galvanic loss D133 that may be present on the surface 133s of the first guard dummies 133 is omitted for sake of simplicity from FIG. 2E.

FIG. 2F is a vertical cross-sectional view of an intermediate structure including the first semiconductor die 141 and the second semiconductor dies 142 according to one or more embodiments. The first semiconductor die 141 and second semiconductor dies 142 may be positioned over the interposer module 10, for example, by using a electromechanical pick-and-place (PNP) machine. The PNP machine may lower the first semiconductor die 141 and second semiconductor dies 142 onto the interposer 10 so that the die bonding layer 146 may be brought into contact with the interposer bonding layer 13 and the die bonding pad 131 may be brought into contact with the interposer bonding pad 132. At this point the die-side interconnect portion 130D may be combined with the interposer-side interconnect portion 130I to complete the assembly of the interconnect 130.

The first semiconductor die 141 and second semiconductor dies 142 may then be bonded to the interposer 10 by performing a bonding (e.g. direct bonding) process. The bonding process may form, for example, a metal-metal bond between the die bonding pads 131 and the interposer bonding pads 132. The bonding process may also form, for example, a dielectric-dielectric bond (e.g., oxide-oxide bond) between the die bonding layer 146 and the interposer bonding layer 13. It should be noted that the bonding process may utilize less than all of the die bonding pads 131, less than all of the interposer bonding pads 132, less than all of the interposer bonding layer 13 and less than all of the die bonding layer 146.

The bonding process may optionally include, for example, a surface preparation step in which a surface of the semiconductor dies 140 and a surface of the interposer bonding layer 13 are prepared by cleaning and removing any contaminants or oxides that could interfere with bonding. The surface preparation step may help to achieve optimal bonding quality. An alignment step may be performed in which the semiconductor dies 140 and the interposer 10 are more precisely aligned to help ensure accurate positioning of the interconnects. The alignment step may be performed, for example, using alignment marks or an optical alignment system. Once aligned, the semiconductor dies 140 and the interposer 10 may be brought into close contact. The bonding process may be performed at room temperature (room-temperature bonding) or at elevated temperatures (thermal bonding) depending on the specific bonding technique used.

In the bonding process, the die bonding layer 131 and the interposer bonding layer 132 may be activated to form a chemical bond (e.g., oxide-oxide bond) at the atomic level. In at least one embodiment, oxide layers in the die bonding layer 146 and the interposer bonding layer 13 may be brought into contact, allowing oxygen atoms to migrate therebetween and form covalent bonds. In at least one embodiment, elevated temperature and pressure may be applied to form the dielectric-dielectric bond (e.g., oxide-oxide bond). Concurrently with the formation of the dielectric-dielectric bond, a metal-metal bond may be formed between the metal layers of the die bonding pads 131 and the interposer bonding pads 132. In at least one embodiment, elevated temperature and pressure may be applied to form the metal-metal bond through diffusion or solid-state reactions.

FIG. 2G illustrates a vertical cross-sectional view of an intermediate structure including the molding material layer 127 according to one or more embodiments. The molding material layer 127 may be formed by dispensing a liquid molding material (e.g., epoxy molding material) onto the intermediate structure of FIG. 2F by a suitable dispensing tool. The molding material layer 127 may be dispensed onto the intermediate structure so as to have a height greater than a height of the upper surface 140a of the semiconductor dies 140.

In at least one embodiment, a dispensing of the molding material may be automated. In particular, various aspects of the dispensing process may be computer-controlled by a control system (e.g., electronic control system; central processing unit (CPU)). In at least one embodiment, a beginning of the dispensing of the molding material, a flow rate of the dispensing of the molding material, and a stopping of the dispensing of the molding material may be controlled by the control system. The control system may be programmed, for example, to dispense a predetermined amount of the molding material based on various input parameters. The input parameters may include, for example, a volume of the space around the interposer 10, a size of the interposer 10, a size of the first semiconductor die 141, a size of the second semiconductor dies 142, etc.

In at least one embodiment, the molding material of the molding material layer 127 may include a capillary material (e.g., capillary underfill type material). The molding material may have a low viscosity. In particular, the viscosity may be less than about 5,000 cP at 10 rpm. In at least one embodiment, the molding material may include a low-viscosity suspension of thermally conductive material (e.g., metal, metal oxide) in prepolymer. The low viscosity may help to facilitate transport of the molding material around the first semiconductor die 141, second semiconductor die 142 and third semiconductor die (not shown). The low viscosity may also help to avoid the formation of voids in the molding material layer 127. In at least one embodiment, the molding material layer 127 may be substantially free of voids.

After the molding material layer 127 has been adequately cured, the molding material layer 127 may be planarized so as to make the upper surface of the molding material layer 127 to be substantially coplanar with the upper surface of the first semiconductor die 141 and second semiconductor dies 142. The molding material layer 127 may be planarized, for example, by grinding, chemical mechanical polishing (CMP) or other suitable planarization technique.

FIG. 2H illustrates a vertical cross-sectional view of an intermediate structure including the plurality of C4 bumps 121, according to one or more embodiments. After the molding material layer 127 has been cured and planarized (e.g., by grinding, CMP, etc.), a second carrier substrate 2 may be attached to the upper surface of the molding material layer 127 and the upper surface 140a of the semiconductor dies 140. The intermediate structure may then be inverted and placed on a work surface.

The first carrier substrate 1 may then be detached from the interposer 10 to expose the interposer lower bonding pads 14a on the board-side surface of the interposer 10. The first carrier substrate 1 may be detached from the interposer 10, for example, by deactivating the adhesive layer (not shown) adhering the first carrier substrate 1 to the interposer 10. The adhesive layer may be deactivated, for example, by a thermal anneal at an elevated temperature (e.g., for a thermally-deactivated adhesive material, or by exposing the adhesive layer to ultraviolet light (e.g., for an ultraviolet-deactivated adhesive material).

The lower passivation layer 14 may then be formed on the board-side surface of the interposer 10. The lower passivation layer 14 may be formed, for example, by depositing (e.g., by CVD, PVD or other suitable deposition technique) a layer of dielectric material on the board-side surface of the interposer 10.

A plurality of openings O14 may then be formed in the lower passivation layer 14 to expose a surface of the interposer lower bonding pads 14a. The openings O14 may be formed by a photolithographic process that may include forming a patterned photoresist mask (not shown) on the lower passivation layer 14, and etching (e.g., wet etching, dry etching, etc.) the exposed upper surface of the lower passivation layer 14 through openings in the photoresist mask. The photoresist mask may be subsequently removed by ashing, dissolving the photoresist mask or by consuming the photoresist mask during the etch process.

The plurality of C4 bumps 121 may then be formed on the intermediate structure. The C4 bumps 121 may include, for example, solder balls formed on the interposer lower bonding pads 14a, for example, by an electroplating process. The plurality of C4 bumps 121 may contact the interposer lower bonding pads 14a through the openings O14 in the lower passivation layer 14. In at least one embodiment, one or more underbump metallization (UBM) layers (not shown) may be formed on the interposer lower bonding pads 14a. The plurality of C4 bumps 121 may then be formed so as to contact the interposer lower bonding pads 14a through the UBM layers.

A plurality of the interposer modules 120 may be formed concurrently on the wafer W120 (see FIG. 2D) in a wafer-level process. After the forming of the C4 bumps 121, a singulation process may be performed in order to singulate the interposer modules 120 on the wafer W120. The singulation process may be performed, for example, by using a dicing saw to saw the interposer 10 (and the molding material 127 formed thereon) along dicing lines.

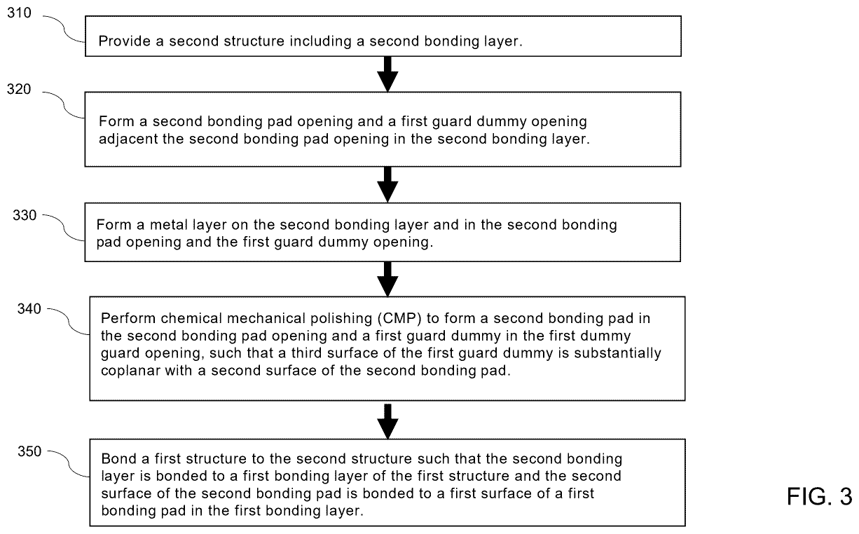

FIG. 3 is a flow chart illustrating a method of forming an interposer module 120 (e.g., semiconductor device) according to one or more embodiments. Step 310 includes providing a second structure including a second bonding layer. Step 320 includes forming a second bonding pad opening and a first guard dummy opening adjacent the second bonding pad opening in the second bonding layer. Step 330 includes forming a metal layer on the second bonding layer and in the second bonding pad opening and the first guard dummy opening. Step 340 includes performing chemical mechanical polishing (CMP) to form a second bonding pad in the second bonding pad opening and a first guard dummy in the first guard dummy opening, such that a third surface of the first guard dummy is substantially coplanar with a second surface of the second bonding pad. Step 350 includes bonding a first structure to the second structure such that the second bonding layer is bonded to a first bonding layer of the first structure and the second surface of the second bonding pad is bonded to a first surface of a first bonding pad in the first bonding layer.

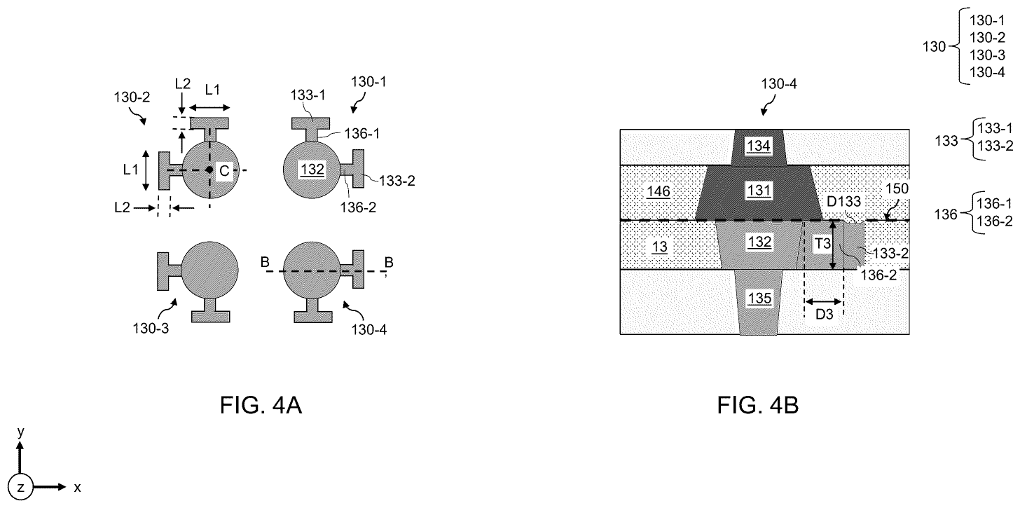

FIGS. 4A-4B illustrate a first alternative design of the interconnect 130 according to one or more embodiments. In particular, FIG. 4A is a top-down view of a plurality of the interconnects 130 having the first alternative design according to one or more embodiments. The die bonding pad 131 and die-side via 134 are omitted from FIG. 4A for ease of understanding. FIG. 4B is a vertical cross-sectional view of one of the plurality of interconnects 130 having the first alternative design according to one or more embodiments. FIG. 4B is a vertical cross-sectional view of the interconnect 130 having the first alternative design along the cross-section B-B′ in FIG. 4A.

As illustrated in FIG. 4A, the interconnects 130 having the first alternative design may include a first interconnect 130-1, second interconnect 130-2, third interconnect 130-3 and fourth interconnect 130-4. The interconnects 130 having the first alternative design may be substantially the same as the interconnects 130 in FIGS. 1A-1D. However, the interconnects 130 having the first alternative design may include a plurality of first guard dummies 133. The plurality of first guard dummies 133 may include a first guard dummy 133-1 and a first guard dummy 133-2. The plurality of first guard dummies 133 may have a substantially rectangular shape. Other shapes are within the contemplated scope of disclosure.

The first guard dummy 133-1 and first guard dummy 133-2 may be formed of the same material as the interposer bonding pad 132. The first guard dummy 133-1 may have substantially the same size and substantially the same shape as the first guard dummy 133-2.

The first guard dummy 133-1 may have a first length L1 in the first direction (x-direction) and a second length L2 less than the first length L1 in the second direction (y-direction). The first guard dummy 133-2 may have the first length L1 in the second direction (y-direction) and the second length L2 less than the first length L1 in the first direction (x-direction). In at least one embodiment, the first length L1 may be at least twice the second length L2.

The interconnects 130 may also include a plurality of connectors 136 including a first connector 136-1 connecting the first guard dummy 133-1 to a first side of the interposer bonding pad 132 and a first connector 136-2 connecting the first guard dummy 133-2 to a second side of the interposer bonding pad 132. The plurality of connectors 136 may be formed of the same material as the first guard dummy 133-1 and the first guard dummy 133-2. The first side of the interposer bonding pad 132 may be separated from the second side of the interposer bonding pad 132 by about 90°. A line of the first connector 136-1 and line of the first connector 136-2 may, therefore, intersect at a center C of the interposer bonding pad 132 and form a substantially 90° angle. Other suitable degrees of separation are within the contemplated scope of disclosure.

As illustrated in FIG. 4A, the interconnects 130 may be arranged in an array including rows in the first direction and columns in the second direction. The interconnects 130 in a row of the interconnects 130 may be arranged such that the first guard dummies 133-1 are substantially aligned in the first direction, and the first guard dummies 133-2 are located on opposite sides of their respective interposer bonding pads 132. The interconnects 130 in a column of the interconnects 130 may be arranged such that the first guard dummies 133-2 are substantially aligned in the second direction, and the first guard dummies 133-1 are located on opposite sides of their respective interposer bonding pads 132.

As illustrated in FIG. 4B, the first connectors 136 (e.g., 136-2) may have a thickness T3 substantially the same as a thickness of the first guard dummies 133 (e.g., 133-2). The first connectors 136 may also have a length (e.g., in the first direction or second direction) that is substantially the same as the first separation distance D3 (e.g., greater than 0.1 μm (e.g., about 0.5 μm)).

As further illustrated in FIG. 4B, the first guard dummies 133 may serve the same function as the first guard dummies 133 in FIGS. 1A-1D. That is, the first guard dummies 133 may guard the interposer bonding pad 132 from damage caused by the galvanic effect during CMP. In particular, an area of galvanic loss D133 may be present on the surface 133s of the first guard dummy 133. However, no area of galvanic loss may be present on the surface 132s of the interposer bonding pad 132.

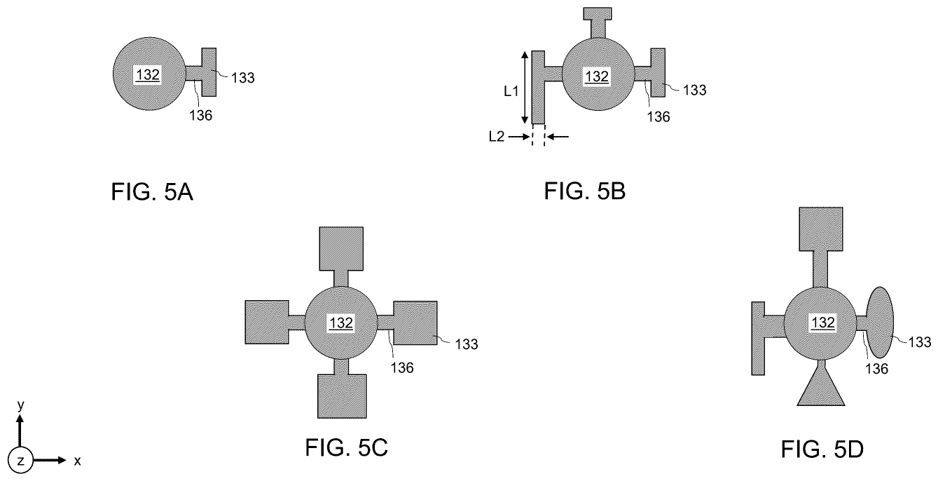

FIGS. 5A-5D illustrate additional alternative designs of the interconnect 130 according to one or more embodiments. The die bonding pad 131 and die-side via 134 are omitted from FIGS. 5A-5D for ease of understanding. In particular, FIG. 5A is a top-down view of an interconnect 130 having a second alternative design according to one or more embodiments. As illustrated in FIG. 5A, the interconnect 130 having the second alternative design may include a first guard dummy 133 and a first connector 136 substantially the same as the first guard dummy 133 and first connector 136 in FIGS. 4A-4B. However, the first guard dummy 133 and the first connector 136 may be located on one side (e.g., only one side) of the interposer bonding pad 132.

FIG. 5B is a top-down view of an interconnect 130 having a third alternative design according to one or more embodiments. As illustrated in FIG. 5B, the interconnect 130 having the third alternative design may include a first guard dummy 133 and a first connector 136 substantially the same as the first guard dummy 133 and first connector 136 in FIGS. 4A-4B. However, the first guard dummy 133 and the first connector 136 may be located on three sides of the interposer bonding pad 132. The three sides may be spaced apart by about 90°.

As further illustrated in FIG. 5B, the first guard dummies 133 may have substantially the same shape (e.g., rectangular shape). However, the first guard dummies 133 may have different sizes. In particular, the first guard dummies 133 may include different first lengths L1 and different second lengths L2.

FIG. 5C is a top-down view of an interconnect 130 having a fourth alternative design according to one or more embodiments. As illustrated in FIG. 5C, the interconnect 130 having the fourth alternative design may include a first guard dummy 133 and a first connector 136 substantially the same as the first guard dummy 133 and first connector 136 in FIGS. 4A-4B. However, the first guard dummy 133 and the first connector 136 may be located on four sides of the interposer bonding pad 132. The four sides may be spaced apart by about 90°. In addition, the first guard dummies 133 in the fourth alternative design may have a substantially square shape.

FIG. 5D is a top-down view of an interconnect 130 having a fifth alternative design according to one or more embodiments. As illustrated in FIG. 5D, the interconnect 130 having the fifth alternative design may include a first guard dummy 133 and a first connector 136 substantially the same as the first guard dummy 133 and first connector 136 in FIG. 5C. However, in the fifth alternative design, the first guard dummy 133 and the first connector 136 may have substantially different shapes including, for example, a rectangular shape, a square shape, an oval shape and a truncated triangular shape. In addition, the connectors 136 in the fifth alternative design may have different sizes (e.g., lengths in the x-direction and y-direction). It should be noted that one or more of the connectors 136 may be omitted from any of the alternative designs in FIGS. 5A-5D.

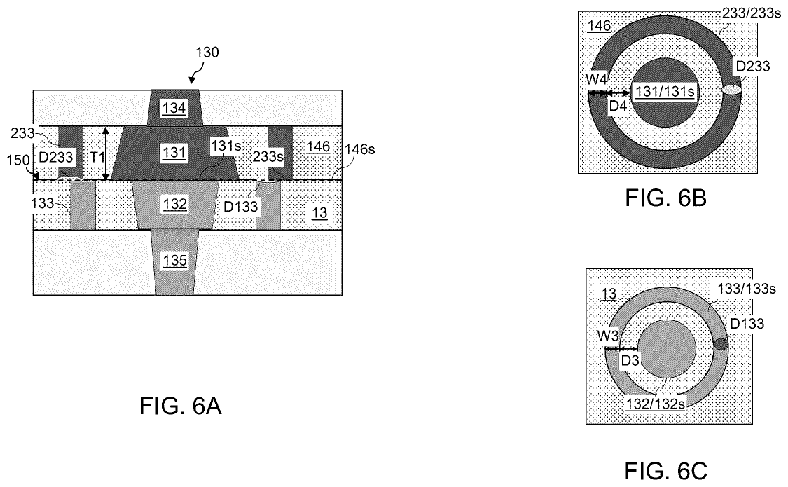

FIGS. 6A-6C are various views of an interconnect 130 having a sixth alternative design according to one or more embodiments. FIG. 6A is a vertical cross-sectional view of the interconnect 130 having the sixth alternative design according to one or more embodiments. FIG. 6B is a bottom-up view of the bond interface 150 in the interconnect 130 having the sixth alternative design according to one or more embodiments. FIG. 6C is a top down view of the bond interface 150 in the interconnect 130 having the sixth alternative design according to one or more embodiments.

As illustrated in FIG. 6A, the interconnect 130 having the sixth alternative design may be substantially the same as the interconnect 130 in FIGS. 1A-1D. However, unlike the interconnect 130 in FIGS. 1A-1D, the interconnect 130 having the sixth alternative design may include a second guard dummy 233. The second guard dummy 233 may be in the die bonding layer 146 and formed around the die bonding pad 131.

In at least one embodiment, the second guard dummy 233 may have a shape (e.g., circular shape) substantially the same as the first guard dummy 133. The second guard dummy 233 may be formed of the same material as the die bonding layer 131. The second guard dummy 233 may have a thickness substantially the same as the thickness T1 of the die bonding pad 131. The second guard dummy 233 may have a width W4 (see FIG. 6B) substantially the same as the width W3 (see FIG. 6C) of the first guard dummy 133. The second guard dummy 233 may be separated from the die bonding pad 131 by a second separation distance D4 (see FIG. 6B) substantially the same as the first separation distance D3 (see FIG. 6C) between the first guard dummy 133 and the interposer bonding pad 132. In at least one embodiment, the width W4 of the second guard dummy 233 may be greater than (e.g., at least 10% greater) than the width W3 of the first guard dummy 133. In at least one embodiment, the second separation distance D4 may be greater (e.g., at least 10% greater) than the first separation distance D3.

A function of the second guard dummy 233 may be substantially similar to a function of the first guard dummy 133. In particular, the second guard dummy 233 may guard the die bonding pad 131 from damage caused by the galvanic effect during a CMP process performed on the surface 146s of the die bonding layer 146, the surface 131s of the die bonding pad 131 and the surface 233s (fourth surface) of the second guard dummy 233. The surface 233s may be substantially coplanar with the surface 131s of the die bonding pad 131. In particular, an area of galvanic loss D233 may be present on the surface 233s of the second guard dummy 233. However, no area of galvanic loss may be present on the surface 131s of the die bonding pad 131.

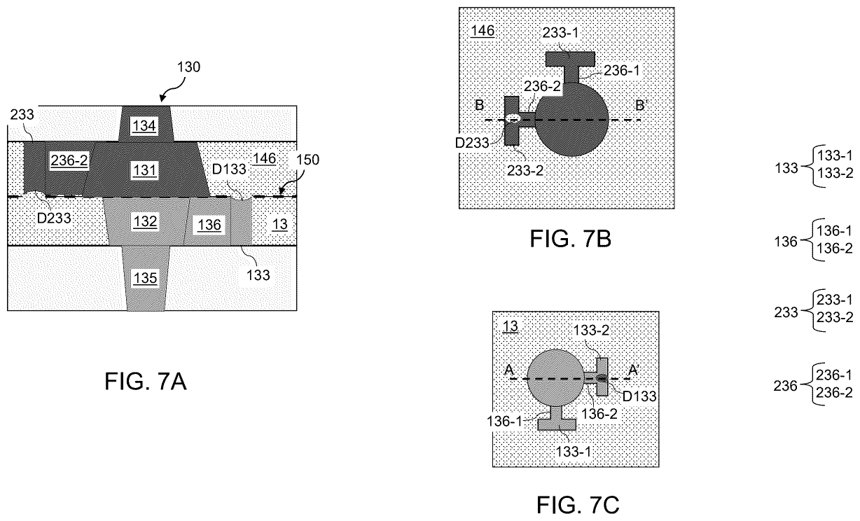

FIGS. 7A-7C illustrate the interconnect 130 having a seventh alternative design according to one or more embodiments. FIG. 7A is a vertical cross-sectional view of the interconnect 130 having the seventh alternative design according to one or more embodiments. FIG. 7B is a bottom-up view of the bond interface 150 in the interconnect 130 having the seventh alternative design according to one or more embodiments. FIG. 7C is a top down view of the bond interface 150 in the interconnect 130 having the seventh alternative design according to one or more embodiments. The view in FIG. 7A is the view along the cross-section B-B′ in FIG. 7B and along the cross-section A-A′ in FIG. 7C.

As illustrated in FIG. 7A, the interconnect 130 having the seventh alternative design may be substantially the same as the interconnect 130 having the first alternative design in FIGS. 4A-4B. That is, the interconnect 130 having the seventh alternative design may include a plurality of first guard dummies 133 and a plurality of first connectors 136 connecting the first guard dummies 133 to the interposer bonding pad 132. However, in the seventh alternative design, the interconnect 130 may also include a plurality of second guard dummies 233 and a plurality of second connectors 236 connecting the second guard dummies 233 to the die bonding pad 132. The plurality of second guard dummies 233 may have a substantially rectangular shape. Other shapes are within the contemplated scope of disclosure.

The second guard dummies 233 may include a second guard dummy 233-1 substantially similar to the first guard dummy 133-1 in FIGS. 4A-4B and a second guard dummy 233-2 substantially similar to the first guard dummy 133-2 in FIGS. 4A-4B. The second connectors 236 may include a second connector 236-1 substantially similar to first connector 136-1 in FIGS. 4A-4B and a second connector 236-2 substantially similar to the first connector 136-2 in FIGS. 4A-4B. The second connector 236-1 may connect the second guard dummy 233-1 to the die bonding pad 131 and the second connector 236-2 may connect the second guard dummy 233-2 to the die bonding pad 131.

A function of the second guard dummy 233-1 and the second guard dummy 233-2 may be substantially similar to a function of the second guard dummy 233 in FIGS. 6A-6C. In particular, the second guard dummy 233-1 and the second guard dummy 233-2 may guard the die bonding pad 131 from damage caused by the galvanic effect during a CMP process performed on the surface 146s of the die bonding layer 146, the surface 131s of the die bonding pad 131 and the surface 233s of the second guard dummy 233. In particular, an area of galvanic loss D233 may be present on the surface 233s of the second guard dummy 233-1 and/or the second guard dummy 233-2. However, no area of galvanic loss may be present on the surface 131s of the die bonding pad 131.

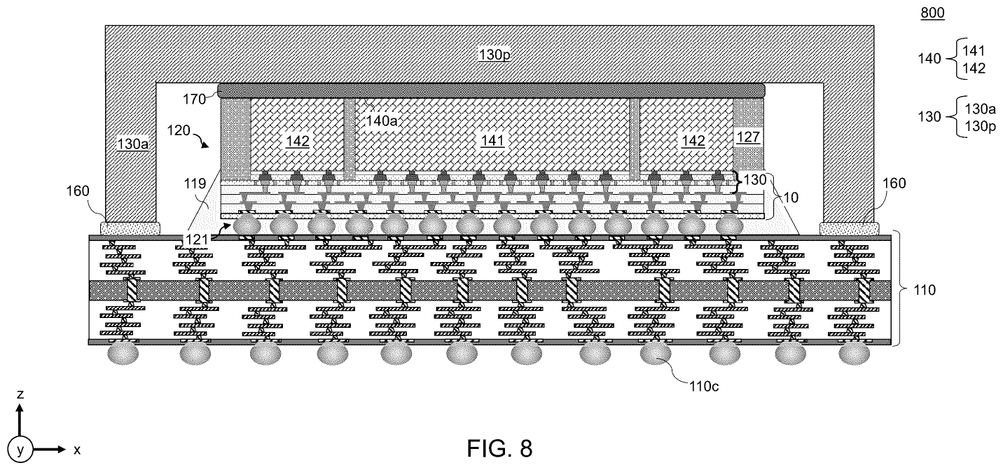

FIG. 8 is a vertical cross-sectional view of a package structure 800 including the interposer module 120 according to one or more embodiments. As illustrated in FIG. 8, the interposer module 120 may be mounted on a package substrate 110. The package substrate 110 may include a cored or coreless package substrate. The package substrate 110 may include a ball-grid array (BGA) including a plurality of solder balls 110c on a board-side surface of the package substrate 110.

The interposer module 120 may be mounted on the package substrate 110 by the plurality of C4 bumps 121 on the board-side surface of the interposer 10. A package underfill 119 may be formed on the package substrate 110 and under and around the interposer 10. The package underfill layer 119 may also be formed around the C4 bumps 121. The package underfill layer 119 may thereby securely fix the interposer module 120 to the package substrate 110. The package underfill layer 119 may be formed of an epoxy-based polymeric material.

A thermal interface material (TIM) layer 170 may be formed on the upper surface 140a of the semiconductor dies 140 and an upper surface of the molding material layer 127. The TIM layer 170 may include, for example, a grease type TIM, a paste type TIM, film type TIM, a gel type TIM, graphite film TIM, a liquid metal TIM (e.g., a gallium-rich TIM), a PCM type TIM, etc. In at least one embodiment, the TIM layer 170 may include a low-melting-temperature (LMT) metal TIM. The PCM type TIM may include, for example, a polymer-based PCM TIM. The PCM type TIM may improve void and delamination issues, enhance thermal contact resistance and improve thermal performance in a package structure 800. In at least one embodiment, the PCM type TIM may change its phase from solid to high viscosity semi liquid around 60° C. In at least one embodiment, the TIM layer 170 may include a gallium base, indium base, silver base, solder base, etc. Other types TIMs in the TIM layer 170 are within the contemplated scope of this disclosure.

The TIM layer 170 may be formed on the interposer module 120 to dissipate heat generated during operation of the package structure 800 (e.g., operation of the semiconductor dies 140). The TIM layer 170 may be attached to the interposer module 120, for example, by a thermally conductive adhesive. The TIM layer 170 may have a low bulk thermal impedance and high thermal conductivity.

A package lid 130 may be located on the TIM layer 170 over the interposer module 120 and connected to the package substrate 110. The bond-line-thickness (BLT) (e.g., a distance between the package lid 130 and the interposer module 120) may be less than about 100 μm, although greater or lesser distances may be used. The package lid 130 may include a package lid plate portion 130p formed on the TIM layer 170 over the interposer module 120. The package lid 130 may also include a package lid foot portion 130a located around an outer periphery of the package lid plate portion 130p. The package lid foot portion 130a may be fixed to the package substrate 110 by an adhesive layer 160.

The package lid 130 may be formed, for example, of metal, ceramic or polymer material. In at least one embodiment, a material of the package lid 130 may include copper with a nickel coating surface. The nickel coating surface may have a thickness in a range of 1 μm to 10 μm. The package lid plate portion 130p may have a plate shape (e.g., planar shape) and be substantially parallel to an upper surface of the package substrate 110. The package lid plate portion 130p may extend, for example, in an x-y plane in FIG. 8. The package lid plate portion 130p may include an outer sidewall that is substantially aligned with an outer sidewall of the package lid foot portion 130a. An upper surface of the package lid plate portion 130p may be substantially parallel to the underside of the package lid plate portion 130p.

The adhesive layer 160 may be formed on the package substrate 110 near the sidewall of the interposer module 120. The adhesive layer 160 may bond the package lid foot portion 130a to package substrate 110. A thickness of the adhesive layer 160 may be in a range from 50 μm to 200 μm. The adhesive layer 160 may include, for example, a silicone adhesive (e.g., containing aluminum oxide, zinc oxide, resin, etc.) or an epoxy adhesive. Other suitable adhesives may be used. The adhesive layer 160 may contact the backside metal layer or the recessed upper surface of the upper molding material layer.

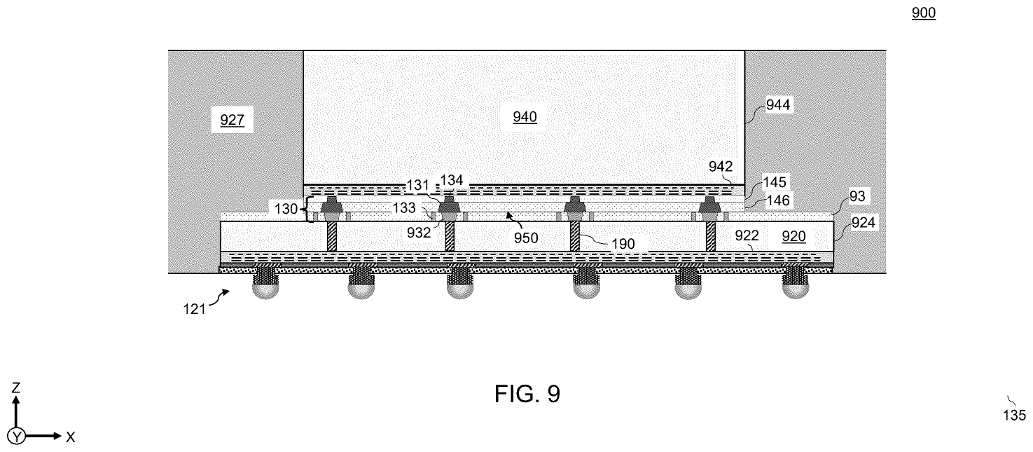

FIG. 9 is a vertical cross-sectional view of a package module 900 including the interconnect 130 according to one or more embodiments. As illustrated in FIG. 9, the package module 900 may include a bottom semiconductor die 920 (e.g., bottom die) and a top semiconductor die 940 (e.g., top die) mounted on the bottom semiconductor die 920. The bottom semiconductor die 920 and top semiconductor die 940 may be substantially the same as the semiconductor dies 140 in FIG. 1A.

The bottom semiconductor die 920 may include an active region 922 (e.g., including transistors, diodes, capacitors, etc.) and a bulk silicon region 924 on the active region 922. The top semiconductor die 940 may include an active region 942 and a bulk silicon region 944 on the active region 942. A molding material layer 927 similar to the molding material layer 127 in FIG. 1A may be formed on and around the bottom semiconductor die 920 and on a side of the top semiconductor die 940. The package module 900 may also include a plurality of C4 bumps 121 on a board-side surface of the package module 900.

As further illustrated in FIG. 9, the bottom semiconductor die 920 may include a lower bonding layer 93 similar to the interposer bonding layer 13 in FIG. 1A. The top semiconductor die 940 may include the dielectric layer 145 and the die bonding layer 146 on the dielectric layer 145. The top semiconductor die 940 may be bonded to the bottom semiconductor die 920 by a bond at a bond interface 950 similar to the bond interface 150 in FIG. 1C. The interconnects 130 may electrically couple the top semiconductor die 940 to the bottom semiconductor die 920 across the bond interface 950.

The interconnects 130 may include the die bonding pad 131 in the die bonding layer 146 and a die-side via 134 in the dielectric layer 145 of the top semiconductor die 940. The interconnects 130 may also include a lower bonding pad 932 (similar to the interposer bonding pad 132 in FIG. 1A) in the lower bonding layer 93 and the first guard dummy 133 in the lower bonding layer 93 adjacent to the lower bonding pad 932. In contrast to the interposer bonding pad 132 in FIG. 1A which contacts the interposer-side via 135, in the package structure 900 the lower bonding pad 932 may contact a through via 190. The through via 190 may be connected to the active region 922 in the bottom semiconductor die 920.

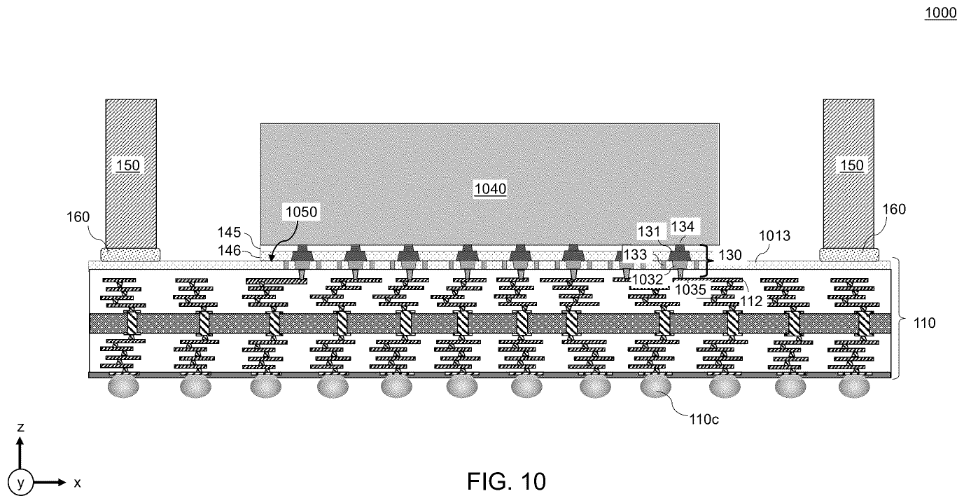

FIG. 10 is a vertical cross-sectional view of a package structure 1000 including the interconnect 130 according to one or more embodiments. As illustrated in FIG. 10, the package structure 1000 may include a semiconductor die 1040 mounted on the package substrate 110. The package structure 1000 may also include a stiffener ring 1000 connected by the adhesive 160 to the package substrate 110 around the semiconductor die 1040.

The semiconductor die 1040 may be substantially the same as any one of the semiconductor dies 140 in FIG. 1A. The semiconductor die 1040 may be bonded to the package substrate 110 by a bond at a bond interface 1050 similar to the bond interface 150 in FIG. 1C. The semiconductor die 1040 may be electrically coupled to the package substrate 110 by a plurality of the interconnects 130.

The package substrate 110 may include a lower bonding layer 1013 similar to the interposer bonding layer 13 in FIG. 1A. The semiconductor die 1040 may include the dielectric layer 145 and the die bonding layer 146 as in FIG. 1A. The interconnects 130 may include the die bonding pad 131 in the die bonding layer 146 and a die-side via 134 in the dielectric layer 145 of the semiconductor die 1040. The interconnects 130 may also include a lower bonding pad 1032 (similar to the interposer bonding pad 132 in FIG. 1A) in the lower bonding layer 1013 and the first guard dummy 133 in the lower bonding layer 1013 adjacent to the lower bonding pad 1032. The interconnects 130 may also include a substrate-side via 1035 (similar to the interposer-side via 135 in FIG. 1A) that connects the lower bonding pad 1032 to the interconnect structures 112 in the package substrate 110.

Referring now to FIGS. 1A-10, an interconnect 130 for a semiconductor device 120, 800, 900, 1000, the interconnect 130 may include a first bonding pad 131 having a first surface 131s, and a second bonding pad 132, 932, 1032 having a second surface 132s bonded to the first surface 131s of the first bonding pad 131, and a first guard dummy 133 adjacent the second bonding pad 132, 932, 1032 and having a third surface 133s substantially coplanar with the second surface 132s of the second bonding pad 132, 932, 1032.

In one embodiment, the first guard dummy 133 may include an electrically isolated metal guard dummy. In one embodiment, the first guard dummy 133 may include an annular shape and may be around the second bonding pad 132, 932, 1032. In one embodiment, the second bonding pad 132, 932, 1032 may include a circular shape and the first guard dummy 133 may be concentrically formed with the second bonding pad 132, 932, 1032. In one embodiment, the first guard dummy 133 may be separated from the second bonding pad 132, 932, 1032 by a first separation distance D3 greater than a width W3 of the first guard dummy 133. In one embodiment, the first separation distance D3 may be at least 30% greater than the width W3 of the first guard dummy 133. In one embodiment, the width W3 of the first guard dummy 133 and the first separation distance D3 are substantially uniform around an entire periphery of the second bonding pad 132, 932, 1032. In one embodiment, the first guard dummy 133 has a third thickness greater than the width W3 of the first guard dummy 133. In one embodiment, the second bonding pad 132, 932, 1032 has a second thickness substantially equal to the third thickness of the first guard dummy 133. In one embodiment, the second bonding pad 132, 932, 1032 and the first guard dummy 133 comprise the same metal material. In one embodiment, the first bonding pad 131 has a first width W1 and the second bonding pad 132, 932, 1032 has a second width W2 less than the first width W1. In one embodiment, the first guard dummy 133 may be connected to the second bonding pad 132, 932, 1032. In one embodiment, the interconnect 130 may further include a second guard dummy 233 adjacent the first bonding pad 131 and having a fourth surface 233s substantially coplanar with the first surface 131s of the first bonding pad 131.

Referring again to FIGS. 1A-10, a semiconductor device 120, 800, 900, 1000, may include a first structure 140, 940, 1040 may include a first bonding layer 146, a second structure 10, 920, 110 bonded to the first structure 140, 940, 1040 by a bond and may include a second bonding layer 13, 93, 1013, and an interconnect 130 electrically coupling the first structure 140, 940, 1040 to the second structure 10, 920, 110, may include a first bonding pad 131 in the first bonding layer 146 and having a first surface 131s, and a second bonding pad 132, 932, 1032 in the second bonding layer 13, 93, 1013 and having a second surface 132s bonded to the first surface 131s of the first bonding pad 131, and a first guard dummy 133 adjacent the second bonding pad 132, 932, 1032 in the second bonding layer 13, 93, 1013 and having a third surface 133s substantially coplanar with the second surface 132s of the second bonding pad 132, 932, 1032.

In one embodiment, the first structure 140, 940, 1040 may include a semiconductor die and the second structure 10, 920, 110 may include one of an interposer 10, a second semiconductor die 920 or a package substrate 110. The interconnect 130 may include a plurality of interconnects 130, and a distance D1, D2 between the plurality of interconnects 130 may be greater than a first separation distance D3 between the first guard dummy 133 and the second bonding pad 132, 932, 1032 in the plurality of interconnects 130. In one embodiment, the first guard dummy 133 may be connected to the second bonding pad 132, 932, 1032. In one embodiment, the interconnect 130 may further include a second guard dummy 233 adjacent the first bonding pad 131 and having a fourth surface 233s substantially coplanar with the first surface 131s of the first bonding pad 131.

Referring again to FIGS. 1A-10, a method of forming a semiconductor device 120, 800, 900, 1000, the method may include providing a second structure 10, 920, 110 including a second bonding layer 13, 93, 1013, forming a second bonding pad opening O132 and a first guard dummy opening O133 adjacent the second bonding pad opening O132 in the second bonding layer 13, 93, 1013, forming a metal layer 132L/133L on the second bonding layer 13, 93, 1013 and in the second bonding pad opening O132 and the first guard dummy opening O133, performing chemical mechanical polishing (CMP) to form a second bonding pad 132, 932, 1032 in the second bonding pad opening O132 and a first guard dummy 133 in the first guard dummy opening O133, such that a third surface 133s of the first guard dummy 133 may be substantially coplanar with a second surface 132s of the second bonding pad 132, 932, 1032, and bonding a first structure 140, 940, 1040 to the second structure 10, 920, 110 such that the second bonding layer 13, 93, 1013 may be bonded to a first bonding layer 146 of the first structure 140, 940, 1040 and the second surface 132s of the second bonding pad 132, 932, 1032 may be bonded to a first surface 131s of a first bonding pad 131 in the first bonding layer 146.

In one embodiment, the performing of the CMP may include guarding the second bonding pad 132, 932, 1032 from damage caused by a galvanic effect by the first guard dummy 133.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, the structure comprising:
a first bonding pad having a first surface;
a second bonding pad having a second surface bonded to the first surface of the first bonding pad; and
a first guard dummy adjacent the second bonding pad and having a third surface substantially coplanar with the second surface of the second bonding pad.

2. The structure of claim 1, wherein the first guard dummy comprises an electrically isolated metal guard dummy.

3. The structure of claim 1, wherein the first guard dummy comprises an annular shape and is around the second bonding pad.

4. The structure of claim 3, wherein the second bonding pad comprises a circular shape and the first guard dummy is concentrically formed with the second bonding pad.

5. The structure of claim 4, wherein the first guard dummy is separated from the second bonding pad by a first separation distance greater than a width of the first guard dummy.

6. The structure of claim 5, wherein the first separation distance is at least 30% greater than the width of the first guard dummy.

7. The structure of claim 5, wherein the width of the first guard dummy and the first separation distance are substantially uniform around an entire periphery of the second bonding pad.

8. The structure of claim 5, wherein the first guard dummy has a third thickness greater than the width of the first guard dummy.

9. The structure of claim 8, wherein the second bonding pad has a second thickness substantially equal to the third thickness of the first guard dummy.

10. The structure of claim 1, wherein the second bonding pad and the first guard dummy comprise the same metal material.

11. The structure of claim 1, wherein the first bonding pad has a first width and the second bonding pad has a second width less than the first width.

12. The structure of claim 1, wherein the first guard dummy is connected to the second bonding pad.

13. The structure of claim 1, further comprising:
a second guard dummy adjacent the first bonding pad and having a fourth surface substantially coplanar with the first surface of the first bonding pad.

14. A semiconductor device, comprising:
a first structure comprising a first bonding layer;
a second structure bonded to the first structure and comprising a second bonding layer; and
an interconnect electrically coupling the first structure to the second structure, comprising:
a first bonding pad in the first bonding layer and having a first surface;
a second bonding pad in the second bonding layer and having a second surface bonded to the first surface of the first bonding pad; and
a first guard dummy adjacent the second bonding pad in the second bonding layer and having a third surface substantially coplanar with the second surface of the second bonding pad.

15. The semiconductor device of claim 14, wherein the first structure comprises a semiconductor die and the second structure comprises one of an interposer, a second semiconductor die or a package substrate.

16. The semiconductor device of claim 14, wherein the interconnect comprises a plurality of interconnects, and a distance between the plurality of interconnects is greater than a first separation distance between the first guard dummy and the second bonding pad in the plurality of interconnects.

17. The semiconductor device of claim 14, wherein the first guard dummy is connected to the second bonding pad.

18. The semiconductor device of claim 14, wherein the interconnect further comprises a second guard dummy adjacent the first bonding pad and having a fourth surface substantially coplanar with the first surface of the first bonding pad.

19. A method of forming a semiconductor device, the method comprising:
providing a second structure comprising a second bonding layer;
forming a second bonding pad opening and a first guard dummy opening adjacent the second bonding pad opening in the second bonding layer;
forming a metal layer on the second bonding layer and in the second bonding pad opening and the first guard dummy opening;
performing chemical mechanical polishing (CMP) to form a second bonding pad in the second bonding pad opening and a first guard dummy in the first guard dummy opening, such that a third surface of the first guard dummy is substantially coplanar with a second surface of the second bonding pad; and
bonding a first structure to the second structure such that the second bonding layer is bonded to a first bonding layer of the first structure and the second surface of the second bonding pad is bonded to a first surface of a first bonding pad in the first bonding layer.

20. The method of claim 19, wherein the performing of the CMP comprises guarding the second bonding pad from damage caused by a galvanic effect by the first guard dummy.
